(19) United States
(12) Patent Application Publication
(10) Pub. No.: US 2025/0196131 A1
(43) Pub. Date: Jun. 19, 2025

(54) AREA-SELECTIVE DEPOSITION USING DIAZIRINES OR DIAZO COMPOUNDS AS OVERLAYER

(71) Applicant: International Business Machines Corporation, Armonk, NY (US)

(72) Inventors: Ishwar Singh, Sunnyvale, CA (US); Rudy J. Wojtecki, San Jose, CA (US)

(21) Appl. No.: 18/540,996

(22) Filed: Dec. 15, 2023

(51) Int. Cl. B01L 3/00; C09D 5/00; C09D 5/16; C09D 165/00; H01L 21/02

(52) U.S. Cl. CPC B01L 3/502715; C09D 5/008; C09D 5/16; C09D 165/00; H01L 21/02118; H01L 21/02304; B01L 2300/0645; B01L 2300/16

(57) ABSTRACT

A method for forming an inhibitor layer on a transition metal surface is provided. The method includes introducing diazo compounds to bind to atoms of the transition metal surface, dosing a monomer to initiate polymerization for building up the inhibitor layer, depositing material onto a growth area adjacent to the transition metal surface and etching the inhibitor layer following completion of the depositing of the material onto the growth area.

### BACKGROUND

This disclosure generally relates to fabrication methods and resulting structures for semiconductor devices. More specifically, this disclosure relates to area-selective deposition using diazirines or diazo compounds as an overlayer.

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### SUMMARY

A method for forming an inhibitor layer on a transition metal surface is provided. The method includes introducing diazo compounds to bind to atoms of the transition metal surface, dosing a monomer to initiate polymerization for building up the inhibitor layer, depositing material onto a growth area adjacent to the transition metal surface and etching the inhibitor layer following completion of the depositing of the material onto the growth area. Additionally or alternatively, the method provides for a new approach to area-selective deposition to achieve growth of desired inhibition layers.

A method for forming an inhibitor layer on a surface including Ruthenium is provided. The method includes introducing diazirines to bind to Ruthenium atoms of the surface, dosing a monomer to initiate polymerization for building up the inhibitor layer, depositing material onto a growth area adjacent to the surface and etching the inhibitor layer following completion of the depositing of the material onto the growth area. Additionally or alternatively, the method provides for a new approach to area-selective deposition to achieve growth of desired inhibition layers and the use of diazirines with Ruthenium, for example, provides for ease of gas phase functionalization and an ability to initiate polymerization by dosing in the monomer.

A method for assembling a biosensor on a transition metal surface is provided. The method includes introducing diazo compounds to bind to atoms of the transition metal surface and to thereby form molecules with reactive functional groups, dosing a monomer to initiate polymerization for building up a support layer between the atoms of the transition metal surface and the molecules with the reactive functional groups and depositing biomolecules onto the molecules with the reactive functional groups to form the biosensor. Additionally or alternatively, the method provides for a new approach to area-selective deposition to achieve growth of desired support layers on which biomolecules can be deposited.

A method for assembling a biosensor on a surface including Ruthenium is provided. The method includes introducing diazirines to bind to Ruthenium atoms of the surface and to thereby form molecules with reactive functional groups, dosing a monomer to initiate polymerization for building up a support layer between the Ruthenium atoms of the surface and the molecules with the reactive functional groups and depositing biomolecules onto the molecules with the reactive functional groups to form the biosensor. Additionally or alternatively, the method provides for a new approach to area-selective deposition to achieve growth of desired support layers on which biomolecules can be deposited and the use of diazirines with Ruthenium, for example, provides for ease of gas phase functionalization and an ability to initiate polymerization by dosing in the monomer.

A semiconductor device is provided and includes a growth area on which a material is to be deposited and a non-growth area adjacent to the growth area. The non-growth area includes a surface including a transition metal and an inhibitor layer disposed on the surface. The inhibitor layer includes molecules with reactive functional groups and polymeric molecules, each of which is interposed between a corresponding one of the molecules with the reactive functional groups and a corresponding transition metal atom of the surface. Additionally or alternatively, the semiconductor device can be employed in a semiconductor manufacturing process.

A biosensor is provided and includes a surface including a transition metal and a support layer disposed on the surface. The support layer includes molecules with reactive functional groups, polymeric molecules, each of which is interposed between a corresponding one of the molecules with the reactive functional groups and a corresponding transition metal atom of the surface and biomolecules deposited onto the molecules with the reactive functional groups. Additionally or alternatively, the biosensor can be employed in process of analyzing an analyte and/or to determine a concentration of an analyte.

Additional technical features and benefits are realized through the techniques of this disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments are apparent from the following detailed description taken in conjunction with the accompanying drawings in which:

FIG. 1 is a schematic illustration of reactivity of diazo compounds in accordance with embodiments;

FIG. 2 is flow diagram illustrating a method for forming an inhibitor layer on a transition metal surface in accordance with embodiments;

FIG. 3 is a graphical flow diagram illustrating the method of FIG. 2 in accordance with embodiments;

FIG. 4 is a side schematic view of a semiconductor device in accordance with embodiments;

FIG. 5 is flow diagram illustrating a method for assembling a biosensor on a transition metal surface in accordance with embodiments;

FIG. 6 is a graphical flow diagram illustrating the method of FIG. 5 in accordance with embodiments;

FIG. 7 is a side schematic view of a biosensor in accordance with embodiments; and

FIG. 8 is a side schematic view of a biomolecule sensing apparatus in accordance with embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

A method for forming an inhibitor layer on a transition metal surface is provided. The method includes introducing diazo compounds to bind to atoms of the transition metal surface, dosing a monomer to initiate polymerization for building up the inhibitor layer, depositing material onto a growth area adjacent to the transition metal surface and etching the inhibitor layer following completion of the depositing of the material onto the growth area. Additionally or alternatively, the method provides for a new approach to area-selective deposition to achieve growth of desired inhibition layers.

The transition metal surface includes one of Ruthenium, Molybdenum, Tantalum, Rhenium and Rhodium and the diazo compounds include diazirines. The use of diazirines with Ruthenium, for example, provides for ease of gas phase functionalization and an ability to initiate polymerization by dosing in the monomer.

The method further includes cleaning the transition metal surface prior to the introducing of the diazo compounds and at least one of the cleaning of the transition metal surface and the etching of the inhibitor layer comprises plasma etching. This effectively prepares the transition metal surface for polymerization.

The introducing of the diazo compounds is executed in solution or in a gaseous phase. This allows the method to be robust.

The dosing is repeated a number of times to build up the inhibitor layer to a predefined height which allows the inhibitor layer to be grown to any height required for a given application.

A method for forming an inhibitor layer on a surface including Ruthenium is provided. The method includes introducing diazirines to bind to Ruthenium atoms of the surface, dosing a monomer to initiate polymerization for building up the inhibitor layer, depositing material onto a growth area adjacent to the surface and etching the inhibitor layer following completion of the depositing of the material onto the growth area. Additionally or alternatively, the method provides for a new approach to area-selective deposition to achieve growth of desired inhibition layers and the use of diazirines with Ruthenium, for example, provides for ease of gas phase functionalization and an ability to initiate polymerization by dosing in the monomer.

The method further includes cleaning the surface prior to the introducing of diazirines and at least one of the cleaning of the surface and the etching of the inhibitor layer comprises plasma etching. This effectively prepares the transition metal surface for polymerization.

The introducing of the diazirines is executed in solution or in a gaseous phase. This allows the method to be robust.

The dosing is repeated a number of times to build up the inhibitor layer to a predefined height which allows the inhibitor layer to be grown to any height required for a given application.

A method for assembling a biosensor on a transition metal surface is provided. The method includes introducing diazo compounds to bind to atoms of the transition metal surface and to thereby form molecules with reactive functional groups, dosing a monomer to initiate polymerization for building up a support layer between the atoms of the transition metal surface and the molecules with the reactive functional groups and depositing biomolecules onto the molecules with the reactive functional groups to form the biosensor. Additionally or alternatively, the method provides for a new approach to area-selective deposition to achieve growth of desired support layers on which biomolecules can be deposited.

The transition metal surface includes one of Ruthenium, Molybdenum, Tantalum, Rhenium and Rhodium and the diazo compounds include diazirines. The use of diazirines with Ruthenium, for example, provides for ease of gas phase functionalization and an ability to initiate polymerization by dosing in the monomer.

The method further includes cleaning the transition metal surface prior to the introducing of the diazo compounds by plasma etching. This effectively prepares the transition metal surface for polymerization.

The introducing of the diazo compounds is executed in solution or in a gaseous phase. This allows the method to be robust.

The dosing is repeated a number of times to build up the support layer to a predefined height which allows the support layer to be grown to any height required for a given application.

The method further includes sensing a biomolecule using the biosensor in order to sense an analyte and/or a concentration of an analyte.

A method for assembling a biosensor on a surface including Ruthenium is provided. The method includes introducing diazirines to bind to Ruthenium atoms of the surface and to thereby form molecules with reactive functional groups, dosing a monomer to initiate polymerization for building up a support layer between the Ruthenium atoms of the surface and the molecules with the reactive functional groups and depositing biomolecules onto the molecules with the reactive functional groups to form the biosensor. Additionally or alternatively, the method provides for a new approach to area-selective deposition to achieve growth of desired support layers on which biomolecules can be deposited and the use of diazirines with Ruthenium, for example, provides for ease of gas phase functionalization and an ability to initiate polymerization by dosing in the monomer.

The method further includes cleaning the surface prior to the introducing of the diazirines by plasma etching. This effectively prepares the transition metal surface for polymerization.

The introducing of the diazirines is executed in solution or in a gaseous phase. This allows the method to be robust.

The dosing is repeated a number of times to build up the support layer to a predefined height which allows the support layer to be grown to any height required for a given application.

The method further includes sensing a biomolecule using the biosensor in order to sense an analyte and/or to determine a concentration of an analyte.

A semiconductor device is provided and includes a growth area on which a material is to be deposited and a non-growth area adjacent to the growth area. The non-growth area includes a surface including a transition metal and an inhibitor layer disposed on the surface. The inhibitor layer includes molecules with reactive functional groups and polymeric molecules, each of which is interposed between a corresponding one of the molecules with the reactive functional groups and a corresponding transition metal atom of the surface. Additionally or alternatively, the semiconductor device can be employed in a semiconductor manufacturing process.

The transition metal includes Ruthenium and the molecules with the reactive functional groups are derived from diazirines. The use of diazirines with Ruthenium, for example, provides for ease of gas phase functionalization and an ability to initiate polymerization by dosing in the monomer during the formation of the semiconductor device.

A biosensor is provided and includes a surface including a transition metal and a support layer disposed on the surface. The support layer includes molecules with reactive functional groups, polymeric molecules, each of which is interposed between a corresponding one of the molecules with the reactive functional groups and a corresponding transition metal atom of the surface and biomolecules deposited onto the molecules with the reactive functional groups. Additionally or alternatively, the biosensor can be employed in process of analyzing an analyte and/or to determine a concentration of an analyte.

The transition metal includes Ruthenium and the molecules with the reactive functional groups are derived from diazirines. The use of diazirines with Ruthenium, for example, provides for ease of gas phase functionalization and an ability to initiate polymerization by dosing in the monomer during the formation of the biosensor.

A biomolecule sensing apparatus is provided and includes the biosensor. The bio sensor includes the surface including the transition metal and the support layer disposed on the surface. The support layer includes the molecules with the reactive functional groups, the polymeric molecules, each of which is interposed between the corresponding one of the molecules with the reactive functional groups and the corresponding transition metal atom of the surface and the biomolecules deposited onto the molecules with the reactive functional groups. The biomolecule sensing apparatus further includes an injection assembly configured to expose an analyte to the biomolecules of the biosensor and circuitry configured to measure a change in an electrical characteristic of the biomolecules of the biosensor when the analyte is exposed to the biomolecules of the biosensor. The biomolecule sensing apparatus can be employed in process of analyzing an analyte and/or to determine a concentration of an analyte.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, in the semiconductor manufacturing industry, there is an ever growing need to increase the number of features in a semiconductor device and to decrease the overall size of each of these features. Typically, semiconductor manufacturing involves repeated executions of deposition processes, lithographic processes and etching processes. Area selective deposition is a type of a deposition process and involves a material being deposited on one surface but not on another adjacent surface. This is typically accomplished through chemical techniques. In an exemplary case, a surface may be provided with a growth area, on which a layer of material is to be area selectively deposited and grown, interposed between non-growth areas, on which no material should be area selectively deposited. This can be achieved in essentially two manners: an activator molecule can be placed on the growth area to encourage and facilitate growth of the material and/or an inhibitor molecule can be placed on the non-growth areas to impede or prevent undesirable material growth.

Regarding the use of the inhibitor, the inhibitor can generally be provided as discrete molecules, such as small-molecule inhibitors and self-assembled monolayers, or polymeric molecules. The discrete molecules can be designed to adhere to metal or a dielectric based on known chemical properties and can be dispensed in a gaseous phase or through a solution. For polymeric molecules, polymers as inhibition layers offer a tailorable strategy in which a molecular weight and size of the inhibiting layer can be varied in a controlled way through careful selection of a starting polymer. Polymers can be grown selectively at a surface using surface-initiated polymerization or in a gaseous phase. Growth of an inhibitor layer by surface-initiated polymerization can be tailored such that the discrete polymeric molecules have a desired length by continually dosing in monomer through solution or in a gaseous phase. However, surface-initiated polymerization can suffer from residual impurities of catalyst molecules that are left behind as well as instances in which different chains become entangled and/or in which chemical reactions begin running away (meaning losing control over the reaction speed). Gas-phase growth provides for integration into current toolsets with inclusions of new recipes and offers cost-effectiveness but is limited by chemistry in that currently used chemicals tend to be self-limiting.

Turning now to an overview of the aspects of the disclosure, one or more embodiments of the disclosure address the above-described shortcomings of the prior art by providing for a new approach to area-selective deposition to achieve growth of desired inhibition layers.

The above-described aspects of the disclosure address the shortcomings of the prior art by providing a method for forming an inhibitor layer on a transition metal surface including introducing diazo compounds to bind to atoms of the transition metal surface, dosing a monomer to initiate polymerization for building up the inhibitor layer, depositing material onto a growth area adjacent to the transition metal surface and etching the inhibitor layer following completion of the depositing of the material onto the growth area.

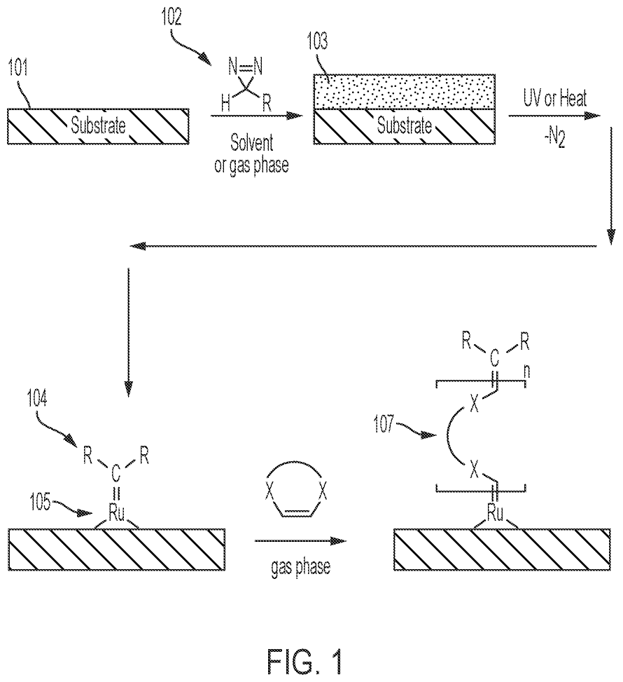

Turning now to a more detailed description of aspects of this disclosure, FIG. 1 depicts a schematic illustration of reactivity of diazo compounds, such as diazirines, with a transition metal surface, such as a surface that includes one or more of Ruthenium, Molybdenum, Tantalum, Rhenium and Rhodium. For purposes of clarity and brevity, the following discussion of FIG. 1 will relate to the case of diazirines reacting with Ruthenium atoms of the surface. As shown in FIG. 1, a substrate 101 is initially provided as a Ruthenium substrate with at least a layer of Ruthenium atoms along its upper surface (one or two layers of Ruthenium atoms may be sufficient). Diazirines 102 are then introduced to the substrate 101 in solvent or gaseous phase to form a precursor layer 103. As used herein, diazirines are a three-membered ring structures, which can generate a molecule with a reactive functional group, such as an active ester, a carboxylic acid, an amine, a ketone, a strained alkyne (such as cyclooctyne) and/or a tetrazine, upon exposure to ultraviolet (UV) light or heat and/or when brought into proximity with certain metals, such as Ruthenium. Thus, in the presence of ultraviolet (UV) light and/or heat, the diazirines react with the Ruthenium atoms to form a molecule with a reactive functional group 104 bonded to a corresponding Ruthenium atom 105. A monomer 106 is then introduced in a gaseous phase. One characteristic of diazirines is that they offer relatively easy gaseous phase functionalization and, due to their ability to make strong double bonds with Ruthenium, they can facilitate initiation of gaseous phase polymerization. Thus, with the monomer 106 introduced in the gaseous phase, polymerization is initiated and a polymeric molecule 107 can be grown between the molecule with the reactive functional group 104 and the Ruthenium atom through strong double bonds. The dosing of the monomer 106 can be repeated a number of times to provide the polymeric molecule with a given length whereby the resultant inhibitor layer 110 has a predefined height H.

It is to be understood that diazirines are a class of organic molecules that include a carbon atom bound to two nitrogen atoms, which are double-bonded to each other, forming a cyclopropane-like ring, 3H-diazirene (>CN2). They are isomeric with diazo carbon groups (>C=N=N), and like them can serve as precursors for carbenes by loss of a molecule of dinitrogen. For example, irradiation of diazirines with UV light leads to carbene insertion into various C—H, N—H, and O—H bonds. Hence, diazirines are useful as small, photo-reactive, crosslinking reagents. They are often used in photoaffinity labeling studies to observe a variety of interactions, including ligand-receptor, ligand-enzyme, protein-protein and protein-nucleic acid interactions.

Diazo compounds, such as diazirines, are incredibly discriminatory and they would not bind to dielectrics such as Silicon Dioxide (SiO₂), Hafnium Oxide (HfO₂) and Zinc Oxide (ZnO), liner material such as Tantalum Nitride (TaN), ceramic material such as Titanium Nitride (TiN) and even coinage elements such as Silver and Gold.

Also, Ruthenium in molecular complexes is not in a 0 oxidation state. Rather, it is oxidized (+2 oxidation state) and operates differently than metallic ruthenium. A Ruthenium surface transiently exhibits this characteristic when diazirine is bound to it. In addition, designing molecules to do polymerization on surfaces is often challenging, and producing a molecular design that works to make a monolayer and also polymerize in a controlled fashion is quite challenging. This a reason why diazirines and the usage of diazirines are quite uncommon in surface sciences.

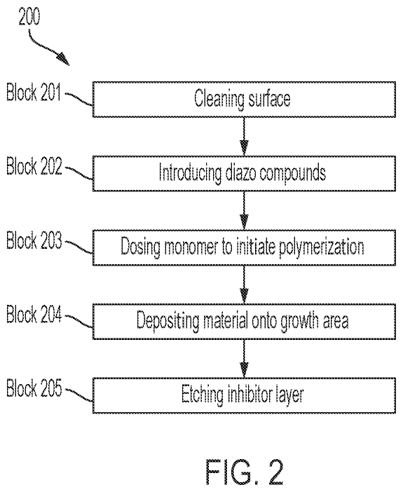

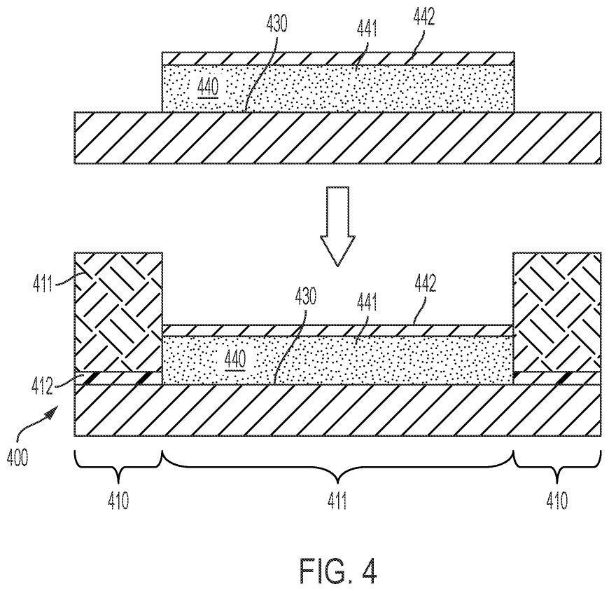

With reference to FIGS. 2-4, a method 200 for forming an inhibitor layer 440 (see FIG. 4) on a transition metal surface 430 (see FIG. 4) is provided. As shown in FIG. 2, the method 200 includes cleaning the transition metal surface (block 201), introducing diazo compounds to bind to atoms of the transition metal surface (block 202), dosing a monomer to initiate polymerization for building up the inhibitor layer (block 203), depositing material, such as precursors (a precursor can be any organometallic molecule for building up a stack for a device through atomic layer deposition (ALD) or other similar techniques), onto a growth area adjacent to the transition metal surface (block 204) and etching the inhibitor layer following completion of the depositing of the material onto the growth area (block 205). In accordance with embodiments, the transition metal surface can include one of Ruthenium, Molybdenum, Tantalum, Rhenium and Rhodium and the diazo compounds can include diazirines. As above, for purposes of clarity and brevity, the following description will relate to the case of the transition metal surface including Ruthenium (i.e., the transition metal surface 430 will be referred to as a Ruthenium surface 430 or a surface with Ruthenium atoms) and the diazo compounds including diazirines.

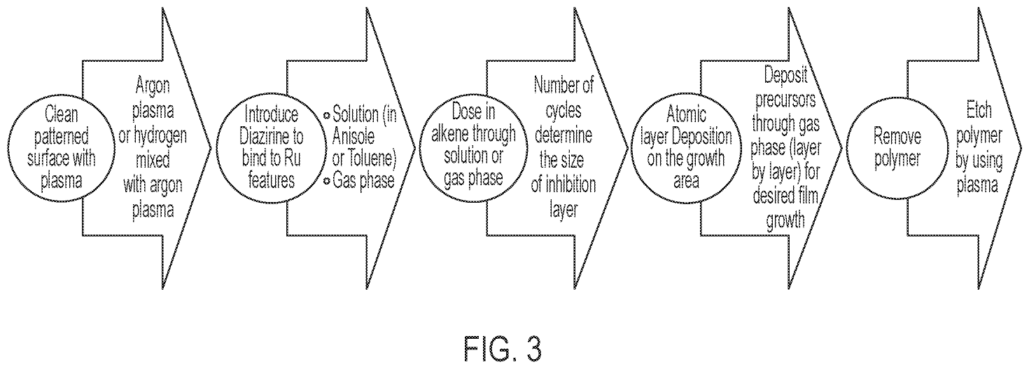

As shown in FIG. 2 and FIG. 3, at least one of the cleaning of the Ruthenium surface of block 201 and the etching of the inhibitor layer of block 205 can include plasma etching, such as argon plasma etching or etching with a mixture of argon and hydrogen. Also, the introducing of the diazirines of block 202 can be executed in a solution of, for example, anisole or toluene, or in a gaseous phase and the dosing of block 203 can be repeated a number of times to build up the inhibitor layer to a predefined height.

As shown in FIG. 4, as a result of an execution of the method 200 of FIG. 2 and an execution of the corresponding method illustrated in FIG. 3, a resultant semiconductor device 400 includes a growth area 410 on which a material 411 is to be deposited and a non-growth area 420, which is adjacent to the growth area 410. The non-growth area 420 includes the Ruthenium surface 430 that includes Ruthenium atoms (i.e., a transition metal surface including at least one or more of Ruthenium atoms, Molybdenum atoms, Tantalum atoms, Rhenium atoms and Rhodium atoms) and an inhibitor layer 440 that is disposed or otherwise formed on the Ruthenium surface 430. The inhibitor layer 440 includes molecules with a reactive functional group 441 and polymeric molecules 442. Each polymeric molecule 442 is respectively interposed between a corresponding one of the molecules with a reactive functional group 441 and a corresponding Ruthenium atom of the Ruthenium surface 430. With the inhibitor layer 440 provided on the Ruthenium surface of the non-growth area 420, precursor material 412 and the material 411 can be sequentially deposited on the growth area 410 as illustrated. Once the deposition of the material 411 is completed, the inhibitor layer 440 can be removed by etching.

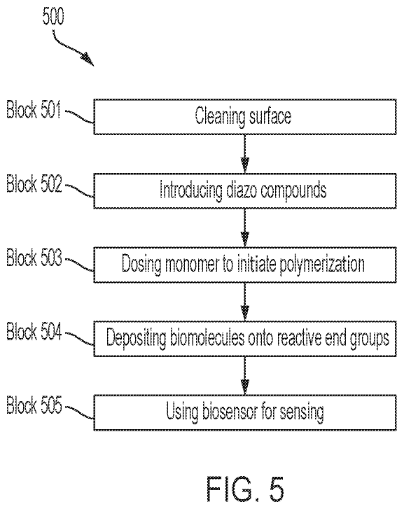

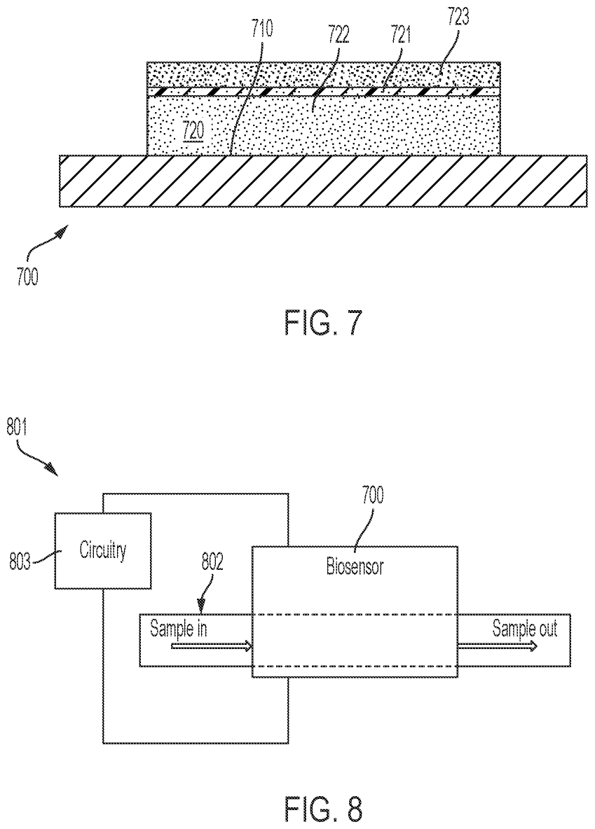

With reference to FIGS. 5-7, a method 500 for assembling a biosensor 700 (see FIG. 7) on a transition metal surface 710 (see FIG. 7) is provided. As shown in FIG. 5, the method 500 includes cleaning the transition metal surface (block 501), introducing diazo compounds to bind to atoms of the transition metal surface and to thereby form molecules with a reactive functional group, such as an active ester, a carboxylic acid, an amine, a ketone, a strained alkyne (such as cyclooctyne) and/or a tetrazine (block 502), dosing a monomer to initiate polymerization for building up a support layer between the atoms of the transition metal surface and the molecules with the reactive functional groups (block 503) and depositing biomolecules onto the molecules with the reactive functional groups to form the biosensor (block 504). The method 500 can also include subsequently using the biosensor for sensing samples, such as biologically relevant samples (block 505). In accordance with embodiments, the transition metal surface can include one of Ruthenium, Molybdenum, Tantalum, Rhenium and Rhodium and the diazo compounds can include diazirines. As above, for purposes of clarity and brevity, the following description will relate to the case of the transition metal surface including Ruthenium (i.e., the transition metal surface 710 will be referred to as a Ruthenium surface 710 or a surface with Ruthenium atoms) and the diazo compounds including diazirines.

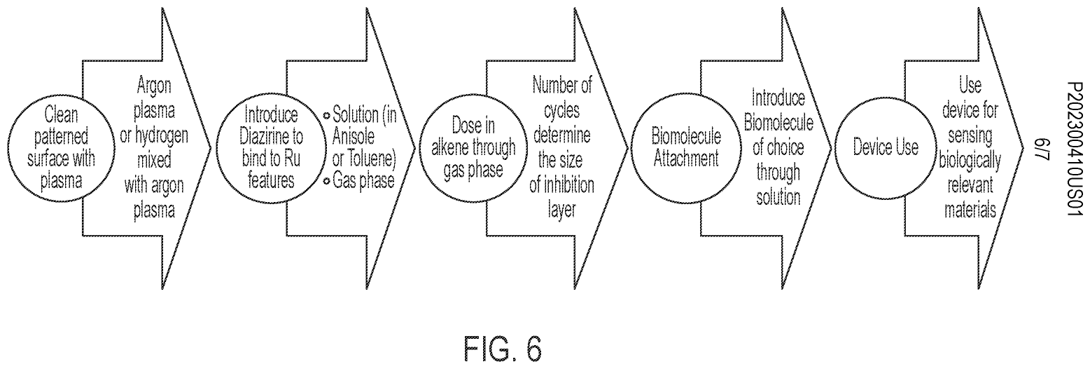

As shown in FIG. 5 and FIG. 6, the cleaning of the Ruthenium surface of block 501 can include plasma etching, such as argon plasma etching or etching with a mixture of argon and hydrogen. Also, the introducing of the diazirines of block 502 can be executed in a solution of, for example, anisole or toluene, or in a gaseous phase and the dosing of block 503 can be repeated a number of times to build up the support layer to a predefined height.

As shown in FIG. 7, as a result of an execution of the method 500 of FIG. 5 and an execution of the corresponding method illustrated in FIG. 6, a resultant biosensor 700 includes the Ruthenium surface 710 and a support layer 720 disposed on the Ruthenium surface 710. The support layer 720 includes molecules with reactive functional groups 721, polymeric molecules 722 and biomolecules 723. Each polymeric molecule 722 is respectively interposed between a corresponding one of the molecules with the reactive functional groups 721 and a corresponding Ruthenium atom of the Ruthenium surface 710. The biomolecules 723 are disposed on the molecules with the reactive functional groups 721.

With continued reference to FIG. 7 and with additional reference to FIG. 8, a biomolecule sensing apparatus 801 is provided and includes the biosensor 700 of FIG. 7, an injection assembly 802 that is configured to expose an analyte, such as a sample of biologically relevant materials, to the biomolecules 723 of the biosensor 700 and circuitry 803, which is configured to measure a change in an electrical characteristic of the biomolecules 723 of the biosensor 700 when the analyte is exposed to the biomolecules 723 of the biosensor 700.

It is to be understood that biosensors that are based on Ruthenium surfaces, such as those described herein, are not available due to difficulties of operation and handling of the metal by itself. Still, an electrochemical sensor could be provided where the electrode surface is made of the metals mentioned herein (mainly Ruthenium though). In these or other cases, as the analyte of interest (biomarkers or small biologically relevant molecules) get close to the biosensor, the analyte would change the electrical response (i.e., impedance) of the surface. This change can be mapped as a function of concentration. An advantage of such as approach is the presence of the strong Carbon-to-Ruthenium bond at the surface as well as the dense polymer that protects and keeps the orientation of biomolecules on top consistent. Another type of sensor could be an optical-based sensor using surface plasmon resonance. Usually Gold is used for this application, however silver is much better, but it undergoes oxidation/corrosion. If a few layers of Ruthenium were grown on the silver surface and then diazirines were used to functionalize, the Ruthenium is a relatively hard element with larger cohesive energy holding atoms together, and thus a polymer could be grown on top and then a biomolecule could be provided. Such a sensor could be used to sense chemical species in real-time.

Various embodiments are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and this disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments will now be provided. Although specific fabrication operations used in implementing one or more embodiments can be individually known, the described combination of operations and/or resulting structures are unique. Thus, the unique combination of the operations described in connection with the fabrication of a semiconductor device according to this disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming an inhibitor layer on a transition metal surface, the method comprising:
introducing diazo compounds to bind to atoms of the transition metal surface;
dosing a monomer to initiate polymerization for building up the inhibitor layer;
depositing material onto a growth area adjacent to the transition metal surface; and
etching the inhibitor layer following completion of the depositing of the material onto the growth area.

2. The method according to claim 1, wherein the transition metal surface comprises one of Ruthenium, Molybdenum, Tantalum, Rhenium and Rhodium and the diazo compounds comprise diazirines.

3. The method according to claim 1, wherein:
the method further comprises cleaning the transition metal surface prior to the introducing of the diazo compounds, and
at least one of the cleaning of the transition metal surface and the etching of the inhibitor layer comprises plasma etching.

4. The method according to claim 1, wherein the introducing of the diazo compounds is executed in solution or in a gaseous phase.

5. The method according to claim 1, wherein the dosing is repeated a number of times to build up the inhibitor layer to a predefined height.

6. A method for forming an inhibitor layer on a surface comprising Ruthenium, the method comprising:
introducing diazirines to bind to Ruthenium atoms of the surface;
dosing a monomer to initiate polymerization for building up the inhibitor layer;
depositing material onto a growth area adjacent to the surface; and
etching the inhibitor layer following completion of the depositing of the material onto the growth area.

7. The method according to claim 6, wherein:
the method further comprises cleaning the surface prior to the introducing of diazirines, and
at least one of the cleaning of the surface and the etching of the inhibitor layer comprises plasma etching.

8. The method according to claim 6, wherein the introducing of the diazirines is executed in solution or in a gaseous phase.

9. The method according to claim 6, wherein the dosing is repeated a number of times to build up the inhibitor layer to a predefined height.

10. A method for assembling a biosensor on a transition metal surface, the method comprising:
introducing diazo compounds to bind to atoms of the transition metal surface and to thereby form molecules with reactive functional groups;
dosing a monomer to initiate polymerization for building up a support layer between the atoms of the transition metal surface and the molecules with the reactive functional groups; and
depositing biomolecules onto the molecules with the reactive functional groups to form the biosensor.

11. The method according to claim 10, wherein the transition metal surface comprises one of Ruthenium, Molybdenum, Tantalum, Rhenium and Rhodium and the diazo compounds comprise diazirines.

12. The method according to claim 10, further comprising cleaning the transition metal surface prior to the introducing of the diazo compounds by plasma etching.

13. The method according to claim 10, wherein the introducing of the diazo compounds is executed in solution or in a gaseous phase.

14. The method according to claim 10, wherein the dosing is repeated a number of times to build up the support layer to a predefined height.

15. The method according to claim 10, further comprising sensing a biomolecule using the biosensor.

16. A method for assembling a biosensor on a surface comprising Ruthenium, the method comprising:
introducing diazirines to bind to Ruthenium atoms of the surface and to thereby form molecules with reactive functional groups;
dosing a monomer to initiate polymerization for building up a support layer between the Ruthenium atoms of the surface and the molecules with the reactive functional groups; and
depositing biomolecules onto the molecules with the reactive functional groups to form the biosensor.

17. The method according to claim 16, further comprising cleaning the surface prior to the introducing of the diazirines by plasma etching.

18. The method according to claim 17, wherein the introducing of the diazirines is executed in solution or in a gaseous phase.

19. The method according to claim 17, wherein the dosing is repeated a number of times to build up the support layer to a predefined height.

20. The method according to claim 17, further comprising sensing a biomolecule using the biosensor.

21. A semiconductor device, comprising:
a growth area on which a material is to be deposited; and
a non-growth area adjacent to the growth area and comprising:
a surface comprising a transition metal; and
an inhibitor layer disposed on the surface and comprising:
molecules with reactive functional groups; and
polymeric molecules, each of which is interposed between a corresponding one of the molecules with the reactive functional groups and a corresponding transition metal atom of the surface.

22. The semiconductor device according to claim 21, wherein the transition metal comprises Ruthenium and the molecules with the reactive functional groups are derived from diazirines.

23. A biosensor, comprising:
a surface comprising a transition metal; and
a support layer disposed on the surface and comprising:
molecules with reactive functional groups;
polymeric molecules, each of which is interposed between a corresponding one of the molecules with the reactive functional groups and a corresponding transition metal atom of the surface; and
biomolecules deposited onto the molecules with the reactive functional groups.

24. The biosensor according to claim 23, wherein the transition metal comprises Ruthenium and the molecules with the reactive functional groups are derived from diazirines.

25. A biomolecule sensing apparatus, comprising:
the biosensor according to claim 23 comprising the surface comprising the transition metal and the support layer disposed on the surface and comprising the molecules with the reactive functional groups, the polymeric molecules, each of which is interposed between the corresponding one of the molecules with the reactive functional groups and the corresponding transition metal atom of the surface and the biomolecules deposited onto the molecules with the reactive functional groups;
an injection assembly configured to expose an analyte to the biomolecules of the biosensor; and
circuitry configured to measure a change in an electrical characteristic of the biomolecules of the biosensor when the analyte is exposed to the biomolecules of the biosensor.
